(19) United States
(12) Patent Application Publication
(10) Pub. No.: US 2002/0195124 A1
(43) Pub. Date: Dec. 26, 2002

(54) Cleaning apparatus of a high density plasma chemical vapor deposition chamber and cleaning method thereof

(76) Inventors: Kyoung Hwan Chin, Kyonggi-do (KR); Sung Joon Hwang, Seoul (KR)

Correspondence Address: VOLENTINE FRANCOS, P.L.L.C., Suite 150, 12200 Sunrise Valley Drive, Reston, VA, 20191, US

(21) Appl. No.: 09/988,302

(22) Filed: Nov. 19, 2001

(30) Foreign Application Priority Data
Jun. 26, 2001 (KR) 2001-0036524

(51) Int. Cl. B08B 9/08; H01L 21/306; C23F 1/00; B08B 9/093; B08B 7/04

(52) U.S. Cl. 134/18; 134/22.18; 156/345.47

(57) ABSTRACT

A cleaning apparatus of a high-density plasma chemical vapor deposition chamber, and a cleaning method thereof, uniformly and sufficiently supplies a cleaning gas into a chamber to uniformly clean the chamber. The cleaning apparatus includes a chamber, an upper electrode provided in an upper portion of the chamber and applied with radio frequency energy, a lower electrode provided below the upper electrode and applied with radio frequency energy, a chuck provided below the upper electrode and formed thereon with the lower electrode to fix a wafer thereon, and three or more cleaning gas nozzles provided at regular intervals on the sidewall of the chamber around the chuck.

### BACKGROUND OF THE INVENTION

1. Field of the Invention

The present invention relates to a cleaning apparatus of a high-density plasma chemical vapor deposition chamber and a cleaning method thereof, and more particularly, to a cleaning apparatus of a high-density plasma chemical vapor deposition chamber and a cleaning method thereof by which a cleaning gas supplied from a radio frequency generator that is provided at a side wall of a chamber is uniformly sprayed into the chamber, thereby effectively performing a cleaning process.

2. Description of the Related Art

Generally, the high-density plasma (HDP) chemical vapor deposition (CVD) process is performed to form insulating layers such as SiO₂ or BiN films between metal layers by a vapor deposition method in processes for fabricating semiconductor devices in the range of approximately 0.5 μm and less. The CVD process is generally performed together with a chemical mechanical polishing process, thereby forming an oxide film of high quality.

While such processes are performed in a HDP CVD chamber, polymers in a powder state, which are by-products produced during the course of the processes, are deposited to a predetermined thickness on the internal surface of a chamber and the deposited polymers come off from the internal surface and are accumulated on a wafer, thereby causing defects in the wafer. Accordingly, the internal surface of chamber requires a periodical cleaning.

The structure and operation of the HDP CVD chamber will be explained with reference to the accompanying drawings, FIG. 1 and FIG. 2.

The conventional HDP CVD chamber 10 as shown in FIG. 1 comprises an upper electrode 12 formed at its upper portion in a bell shape and having high radio frequency (RF) energy applied thereto, and a lower electrode 14 formed on a chuck 16 for fixing a wafer at the center part of the chamber 10.

In addition, a plurality of process gas nozzles 18 are provided at regular intervals on the sidewall of the chamber 10 for supplying a process gas to be sprayed into the space between the upper and lower electrodes 12, 14. A cleaning gas nozzle 20 for spraying the cleaning gas upward is provided at a predetermined portion of the chamber 10 that is positioned below the process nozzle 18.

The operation of the chamber is as follows. When a wafer is placed into the chamber 10 and fixed to the lower electrode 14 of the chuck 16, the process gas is ejected into the space between the upper electrode 12 and the lower electrode 14, i.e., above the wafer. And, the radio frequency energy is applied to the upper and lower electrodes 12, 14 so that the process gas is changed into a plasma state, i.e., excited. The excited process gas serves to react with a portion of wafer exposed from a photoresist mask pattern to make an oxide film.

At this time, byproducts created during such processes, i.e., various types of polymers, are continuously deposited on the internal surface of the chamber 10. As a result, the internal surface of the chamber 10 should be cleaned periodically, regardless of whether a wafer is positioned on the lower electrode 14.

The cleaning process for removing polymers deposited on the internal sidewall of the chamber 10 is as follows. A predetermined cleaning gas is first supplied into the chamber 10 through the cleaning gas nozzle 20 in a state where a wafer is not introduced into the chamber 10. In such a state, when the RF energy is applied to the upper and lower electrodes 12, 14, the cleaning gas is excited into a plasma state. As a result, electrons and ions become different in their speed, and thereby positive ions are gathered at the internal sidewall of the chamber 10 to form a direct current voltage there. The cleaning gas having a DC voltage characteristic reacts with the polymer deposited on the side wall of the chamber to remove it by the electric power. In this way, the cleaning process is performed.

However, in the conventional prior art, there is a problem that since only one cleaning gas nozzle for supplying a cleaning gas into the chamber is provided at one side of the chamber, the cleaning gas being supplied through the nozzle cannot be uniformly sprayed into the chamber. In other words, since the cleaning gas is concentrated in one side of the chamber, a portion of the chamber adjacent to the nozzle is relatively cleaned more than on a portion remote from the nozzle.

Such an incomplete cleaning process causes a decrease in uniformity of the processes after the cleaning process and causes contamination and defects in a wafer because polymers concentrated on the one side of the chamber easily fall off the side wall of the chamber onto the wafer. As a result, the period of time between the cleaning processes gradually is decreased, thereby decreasing the rate of operation of the facility and, accordingly, the productivity. In addition, there is a problem that the elements of the chamber should be disjointed and assembled in order to clean the internal side of the chamber after a predetermined period lapses, thereby increasing working hours and decreasing operation efficiency.

Particularly, the polymer on the internal side of the chamber is deposited thicker on the center portion of the dome shaped upper electrode than on the other portions of the chamber. In addition, the center portion of the upper electrode is remote from the cleaning nozzle, such that the cleaning gas cannot reach as much to clean the center portion of the electrode as the other portions of the chamber. Accordingly, the polymer on the center portion of the chamber falls off onto a wafer more than that on the other portions, thereby causing a failure in process and a defect in a wafer.

### SUMMARY OF THE INVENTION

To solve the problems as described above, it is an object of the present invention to provide a cleaning apparatus of a high-density plasma chemical vapor deposition chamber and a cleaning method thereof by which a cleaning gas is uniformly and sufficiently supplied into a chamber to uniformly clean the chamber, thereby increasing uniformity in processes and preventing contamination and damage of the wafer.

It is another object of the present invention to provide a cleaning apparatus of a high-density plasma chemical vapor deposition chamber and a cleaning method thereof by which a period between cleanings of the internal side of a chamber can be extended thereby increasing the productivity, the operation efficiency, the quality of semiconductor device fabricated and the like, and reducing working hours.

Accordingly, a cleaning apparatus of a high-density plasma chemical vapor deposition chamber comprises: a chamber; an upper electrode provided in an upper side of the chamber and applied with a radio frequency; a lower electrode provided below the upper electrode and applied with a radio frequency; a chuck provided below the upper electrode and formed thereon with the lower electrode to fix a wafer thereon; and three or more cleaning gas nozzles provided at regular intervals on the sidewall of the chamber around the chuck.

In addition, it is preferred that the cleaning gas nozzle be bent toward the upper center of the chamber relative to an upper surface of the chuck.

It is desirable that the cleaning gas nozzle be bent in a spiral form toward the center portion of the chamber and in a direction of from the lower portion to the upper portion relative to the upper surface of the chuck.

It is preferred that the cleaning gas is NF₃.

In another aspect, a cleaning method of cleaning a high-density plasma chemical vapor deposition chamber comprises the steps of: supplying a cleaning gas into the chamber through cleaning gas nozzles provided at the sidewall of the chamber so that the gas fills the space between an upper electrode and a lower electrode; and controlling the amount of the cleaning gas to be supplied in response to the thickness of polymer deposited on an internal sidewall of the chamber.

The cleaning gas may be ejected with a predetermined elevation angle toward the center of the chamber from the sidewall of the chamber.

### BRIEF DESCRIPTION OF THE DRAWINGS

The foregoing and other objects, aspects and advantages will be better understood from the following detailed description of preferred embodiments of the invention with reference to the drawings, in which;

FIG. 1 is a cross sectional view showing the structure of a chamber in which a high density plasma chemical vapor deposition is performed according to the conventional prior art;

FIG. 2 is a cross sectional overview showing the arrangement of a cleaning gas supply nozzle in the chamber shown in FIG. 1;

FIG. 3 is a cross sectional view showing the structure of chamber in which a high density plasma chemical vapor deposition is performed according to an embodiment of the present invention;

FIG. 4 is a cross sectional overview showing the arrangement of a cleaning gas supply nozzle in the chamber shown in FIG. 3; and

FIG. 5 is a plane view showing the arrangement of a cleaning gas supply nozzle in the chamber shown in FIG. 3 according to another embodiment of the present invention.

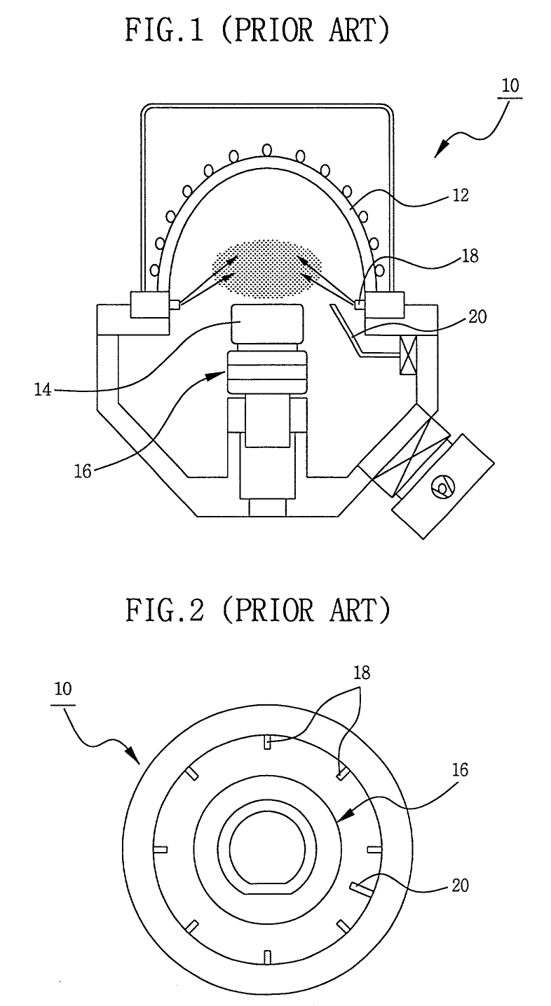

### DETAILED DESCRIPTION OF THE PREFERRED EMBODIMENTS

Herein after, the present invention will be described in detail with reference to the accompanying drawings. It should be noted that like reference numerals are used through the accompanying drawings for designation of like or equivalent parts or portion for simplicity of illustration and explanation. Also, in the following description, specifications will be made to provide a thorough understanding about the present invention. It is apparent to one skilled in the art that the present invention can be achieved without the specifications. There will be omission of detailed description of well-known functions and structures, to clarify key points of the present invention.

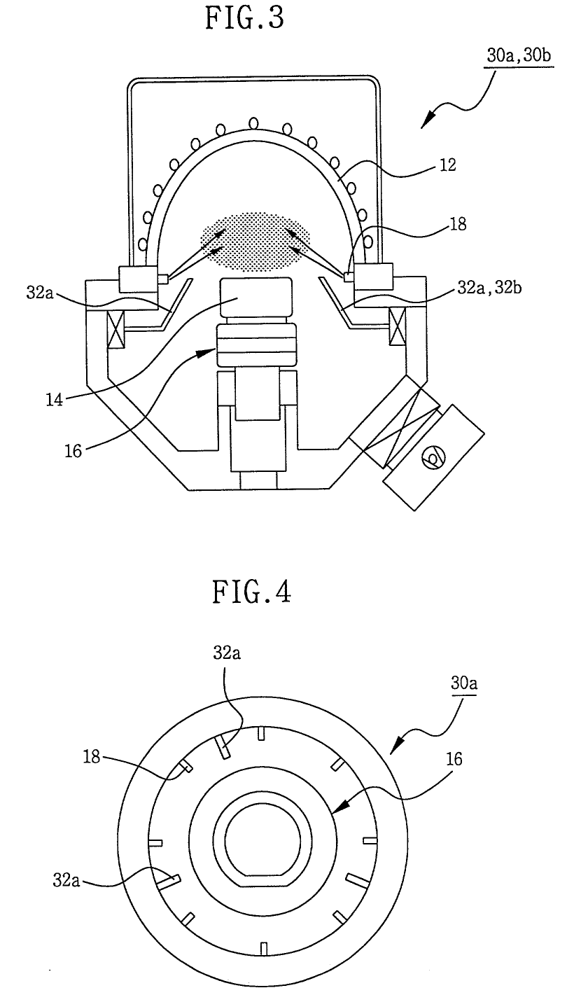

FIGS. 3 to 5 show a cleaning apparatus of a high-density plasma chemical vapor deposition chamber 30a, 30b, having formed therein a space housed within a dome shaped upper electrode 12. The upper electrode 12 is provided in an upper side of the chamber and applied with radio frequency energy. A lower electrode 14 is provided below the upper electrode 12 and applied with radio frequency energy. A chuck 16 is provided below the upper electrode 12 and formed thereon with the lower electrode 14 to fix a wafer thereon. A plurality of process gas nozzles 18 are provided at regular intervals on the sidewall of the chamber 30a, 30b so that a process gas is ejected into the space between the upper electrode 12 and lower electrode 14. Three or more cleaning gas nozzles 32a, 32b are provided at regular intervals on the sidewall of the chamber 30a, 30b below the process gas nozzle 18 so that a cleaning gas is ejected into the space between the upper electrode 12 and lower electrode 14.

In addition, it is preferred that the cleaning gas nozzle 32a, 32b be bent toward the upper center of the chamber 30a, 30b relative to an upper surface of the chuck 16 and the lower electrode 14, so that the cleaning gas is ejected into the space between the electrodes 12, 14 with a predetermined pressure by a controller (not shown).

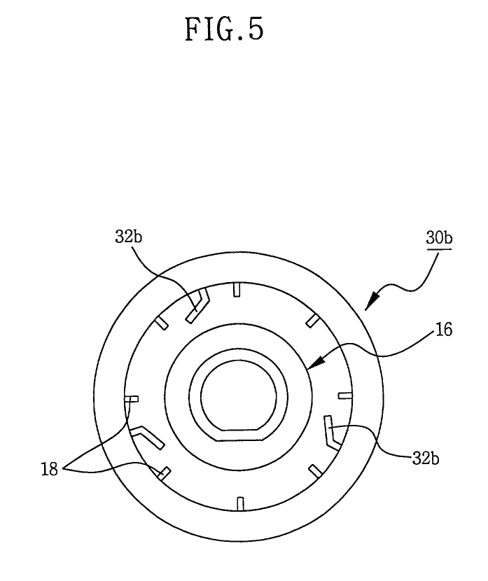

As shown in FIG. 5, the cleaning gas nozzles 32a, 32b may be bent in a spiral form toward the center portion of the chamber 30a, 30b and in a direction from the lower portion to the upper portion relative to the upper surface of the chuck 16.

At this time, the cleaning gas used is NF₃.

The operation of the chamber is as follows. When a wafer is placed into the chamber 30a, 30b and fixed to the lower electrode 14 of the chuck 16, the process gas is ejected into the space between the upper electrode 12 and the lower electrode 14, i.e., above the wafer through the process gas nozzle 18. And, the radio frequency energy is applied to the upper and lower electrodes 12, 14 so that the process gas is changed into a plasma state, i.e., excited. The excited process gas serves to react with a portion of the wafer that is exposed from a photoresist mask pattern to make an oxide film.

At this time, byproducts created during such processes, i.e., various types of polymers, are continuously deposited on the internal surface of the chamber 30a, 30b. As a result, the internal surface of the chamber 30a, 30b should be cleaned periodically, regardless of whether a wafer is positioned on the lower electrode 14.

The cleaning process for removing polymers deposited on the internal sidewall of the chamber 30a, 30b is as follows. A predetermined cleaning gas is first supplied into the chamber 30a, 30b through the cleaning gas nozzles 32a, 32b in a state wherein a wafer is not introduced into the chamber 30a, 30b. At this time, since the cleaning gas nozzle 32a, 32b are arranged at regular intervals around the chuck 16, the cleaning gas is uniformly sprayed into the chamber 30a, 30b with a predetermined ejection pressure by a controller.

The cleaning gas is ejected toward the center of the chamber 30a, 30b and may be first concentrated at the center of the chamber 30a, 30b. However, the cleaning gas is uniformly and continuously diffused toward the sidewall of the chamber, thereby forming a uniformed distribution of the cleaning gas in the chamber.

In addition, as shown in FIG. 5, since each of the cleaning gas nozzles 32b is bent in a spiral shape relative to the center of the chuck 16, the cleaning gas ejected through the nozzles rotates along the internal sidewall of the chamber 30b, thereby being uniformly distributed in all directions in the chamber 30b. At this time, the density of the cleaning gas is increased at the center portion of the chamber 30b by the rotation of the cleaning gas. As a result, the cleaning gas moves toward the upper portion of the chamber 30b and reaches the upper center portion of the dome shaped upper electrode 12, thereby being distributed in the whole space of the chamber 30b, resulting from a diffusion phenomenon and concentrated density at the center portion of the chamber 30b although the cleaning gas itself is heavy.

In such a way, when the cleaning gas is uniformly distributed in the whole space of the chamber, the RF energy is applied to the upper and lower electrodes 12, 14 and the cleaning gas is excited into a plasma state. As a result, electrons and ions become different in their speed, and thereby positive ions are collected on the internal sidewall of the chamber 30a, 30b to form a direct current voltage thereon. The cleaning gas having a DC voltage characteristic reacts with the polymer deposited on the internal sidewall of the chamber to remove it by the electric power. In this way, the cleaning process is performed.

As shown in FIG. 5, since the cleaning gas is rotated and ejected in a predetermined direction, even the upper center portion of the upper electrode 12, where more polymer is deposited than in the other portions of the upper electrode 12, can be entirely cleaned by the rotating cleaning gas, thereby increasing the efficiency in the cleaning operation.

The ejection pressure of the cleaning gas can be controlled while the cleaning gas is supplied through the cleaning gas nozzle 30b so that the degree of the cleaning efficiency may be controlled.

A plurality of cleaning gas nozzles are uniformly arranged in the chamber, the cleaning gas is supplied so that the cleaning gas is uniformly distributed in all directions in the chamber, and therefore the cleaning process is effectively performed, and a wafer from being damaged, contaminated and made defective by polymer.

While the invention has been described in terms of preferred embodiments, those skilled in the art will recognize that the invention can be practiced with modifications within the sprit and scope of the appended claims.

What is claimed is:

1. A cleaning apparatus of a high-density plasma chemical vapor deposition chamber, comprising:
a chamber formed with a closed space therein;
an upper electrode provided in an upper portion of the chamber and applied with radio frequency energy;
a lower electrode provided below the upper electrode and applied with radio frequency energy;
a chuck provided below the upper electrode and formed thereon with the lower electrode to fix a wafer thereon; and
at least three cleaning gas nozzles provided at regular intervals on a sidewall of the chamber around the chuck.

2. The apparatus as claimed in claim 1, wherein at least one cleaning gas nozzle is bent toward an upper center of the chamber relative to an upper surface of the chuck..

3. The apparatus as claimed in claim 2, wherein each cleaning gas nozzle is bent toward an upper center of the chamber relative to an upper surface of the chuck.

4. The apparatus as claimed in claim 1, wherein at least one cleaning gas nozzle is bent in a spiral form toward a center portion of the chamber and in a direction from a lower portion to an upper portion relative to an upper surface of the chuck.

5. The apparatus as claimed in claim 1, wherein the cleaning gas is NF₃.

6. A method of cleaning a high-density plasma chemical vapor deposition chamber, comprising:
supplying a cleaning gas into the chamber through cleaning gas nozzles provided at a sidewall of the chamber so that the cleaning gas fills a space between an upper electrode and a lower electrode in the chamber, increasing a density of the cleaning gas at a center portion of the chamber and projecting the cleaning gas to an upper portion of the chamber; and
controlling an amount of the cleaning gas to be supplied in response to a thickness of polymer deposited on the sidewall of the chamber.

7. The cleaning method as claimed in claim 6, wherein the cleaning gas is projected from the sidewall of the chamber with a predetermined elevation angle toward the center of the chamber and around the sidewall of the chamber.

8. A method of cleaning a high-density plasma chemical vapor deposition chamber, comprising:
supplying a cleaning gas into the chamber through at least three cleaning gas nozzles provided along a sidewall of the chamber so that the cleaning gas fills a space between an upper electrode and a lower electrode in the chamber; and
projecting the cleaning gas to an upper portion of the chamber.

9. The method of claim 8, wherein the cleaning gas is projected from the sidewall of the chamber with a predetermined elevation angle toward the center of the chamber.
